(19) United States
(12) Patent Application Publication
(10) Pub. No.: US 2015/0200326 A1
(43) Pub. Date: Jul. 16, 2015

(54) METHOD AND APPARATUS FOR INCREASING EFFICIENCY OF THIN FILM PHOTOVOLTAIC CELL

(71) Applicant: TSMC Solar Ltd., Taichung City (TW)

(72) Inventor: Chia-Hung TSAI, Kaohsiung City (TW)

(73) Assignee: TSMC Solar Ltd., Taichung City (TW)

(21) Appl. No.: 14/152,004

(22) Filed: Jan. 10, 2014

(51) Int. Cl. H01L 31/18; H01L 31/0224

(52) U.S. Cl. CPC H01L 31/1888; H01L 31/022466

(57) ABSTRACT

A method of fabricating a photovoltaic cell, and apparatus formed by the method, yields increased quantum efficiency. A back contact layer is formed above a substrate. An absorber layer is formed above the back contact layer. A buffer layer is formed above the absorber layer. A transparent conductive layer is formed above the buffer layer. A surface of the transparent conductive layer is treated with an acid to increase roughness of the surface.

### BACKGROUND

This disclosure relates to thin film photovoltaic cells.

Photovoltaic devices (also referred to as photovoltaic cells or solar cells) absorb sunlight and convert energy from photons into electricity. Photovoltaic devices and manufacturing methods therefore are continually evolving to provide higher conversion efficiency with thinner designs. Thin film solar cells are based on one or more layers of thin films of photovoltaic materials deposited on a substrate. The film thickness of the photovoltaic materials ranges from several nanometers to tens of micrometers. Examples of such photovoltaic materials include cadmium telluride (CdTe), copper indium gallium selenide (CIGS) and amorphous silicon (α-Si). These materials function as light absorbers. A photovoltaic device can further comprise other thin films such as a buffer layer, a back contact layer, and a front contact layer. The buffer layer and the absorber layer, which both comprise a semiconductor material, provide a p-n or n-p junction. When the absorber layer absorbs sunlight, electric current can be generated at the p-n or n-p junction.

The quantum efficiency (QE), or incident photon to converted electron (IPCE) ratio, of a solar cell is the percentage of photons incident to the device's photoreactive surface that produce charge carriers. QE indicates electrical sensitivity of the device to light. External quantum efficiency (EQE) refers to the ratio of the number of charge carriers collected by the solar cell to the number of incident photons of a given energy (i.e., incident upon the solar cell from the outside). Another measure of efficiency, internal quantum efficiency (IQE), is the ratio of the number of charge carriers collected by the solar cell to the number of incident photons of a given energy that are absorbed by the solar cell.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a cross-sectional view of layers of a solar cell prior to acid treatment of the surface of a transparent conductive layer in accordance with some embodiments of the present disclosure.

FIG. 1B is a cross-sectional view of layers of a solar cell after acid treatment of a transparent conductive layer in accordance with some embodiments.

FIG. 2 is a flow diagram of a process for fabricating a solar cell in accordance with some embodiments.

FIGS. 3A-3B are cross-sectional illustrations of light pathways without and with acid treatment of a transparent conductive layer.

FIG. 4 is a depiction of a root mean square surface roughness computation.

FIG. 5 is an illustration of treating a surface of a transparent conductive layer with acid vapor in accordance with some embodiments.

FIG. 6 is an experimental plot of increase in external quantum efficiency due to acid immersion, versus light wavelength, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

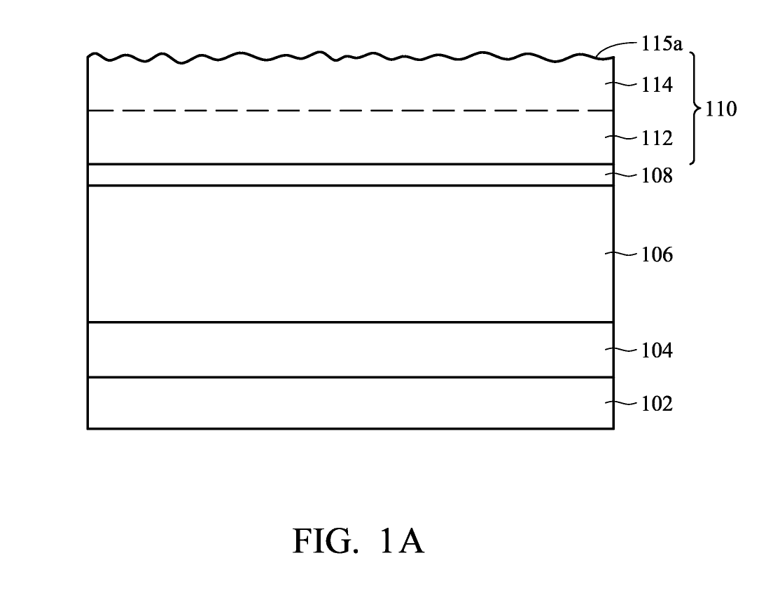

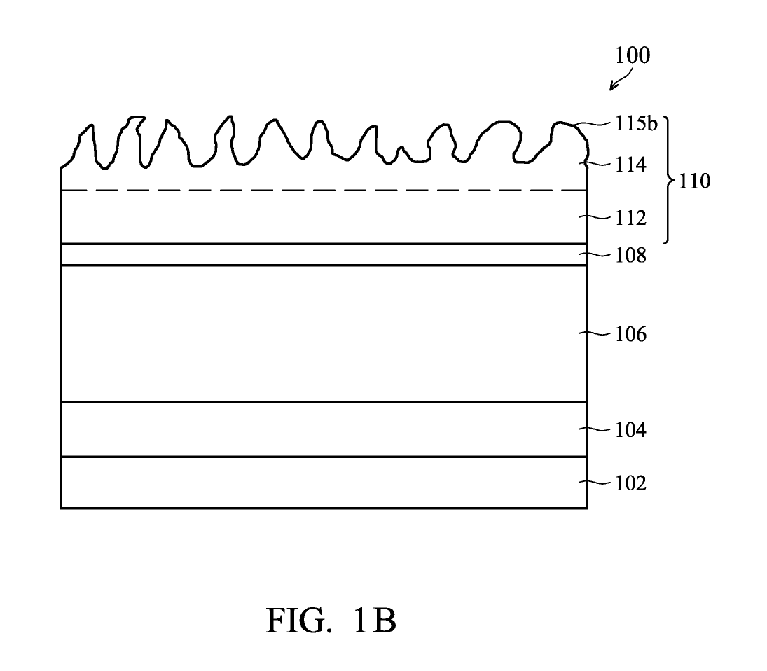

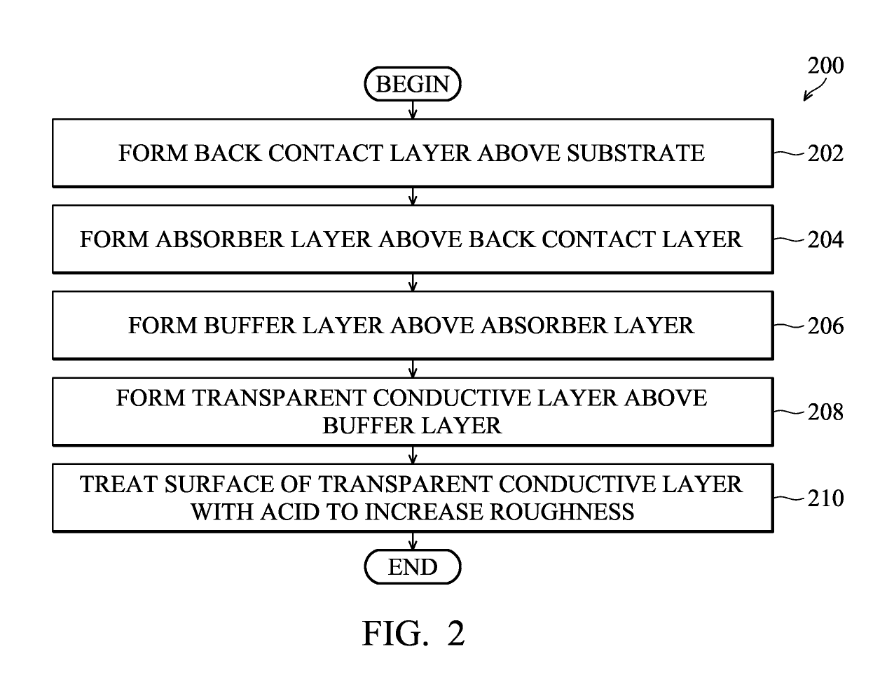

FIGS. 1A-1B are cross-sectional views of a portion of an exemplary photovoltaic device 100 in accordance with some embodiments. FIG. 2 illustrates an exemplary method 200 of fabricating exemplary photovoltaic device 100 in accordance with some embodiments.

At step 202, a back contact layer 104 is formed above a substrate 102. Substrate 102 and back contact layer 104 are made of any materials suitable for such layers in thin film photovoltaic devices. Examples of materials suitable for use in substrate 102 include but are not limited to glass (e.g., soda lime glass), polymer (e.g., polyimide) film and metal foils (such as stainless steel). The film thickness of substrate 102 is in any suitable range, for example, in the range of 0.1 mm to 5 mm in some embodiments.

In some embodiments, substrate 102 can itself include two or more sublayers. For example, a lower sublayer can comprise soda lime glass or other glass capable of tolerating a process at a temperature higher than 600° C., and an upper sublayer can comprise silicon oxide having a formula SiOₓ (where x ranges from 0.3 to 2), which can be used to block possible diffusion of sodium in the lower sublayer.

Examples of suitable materials for back contact layer 104 include, but are not limited to, molybdenum (Mo), copper (Cu), nickel (Ni), or any other metals or conductive material. Back contact layer 104 can be selected based on the type of thin film photovoltaic device. For example, in a CIGS thin film photovoltaic device, back contact layer 104 is Mo in some embodiments. Unless expressly indicated otherwise, references to “CIGS” made in this disclosure will be understood to encompass a material comprising copper indium gallium sulfide and/or selenide, for example, copper indium gallium selenide, copper indium gallium sulfide, or copper indium gallium sulfide/selenide. A selenide material can comprise sulfide or selenide can be completely replaced with sulfide.

In a CdTe thin film photovoltaic device, back contact layer 104 is copper or nickel in some embodiments. The thickness of back contact layer 104 is on the order of nanometers or micrometers, for example, in the range from 100 nm to 20 microns. The thickness of back contact layer 104 is in the range of from 200 nm to 10 microns in some embodiments.

At step 204, an absorber layer 106 comprising an absorber material is formed above back contact layer 104 and above substrate 102. The resulting structure of photovoltaic device 100 is illustrated in FIG. 1B.

Absorber layer 106 is a p-type or n-type semiconductor material. Examples of materials suitable for absorber layer 106 include but are not limited to cadmium telluride (CdTe), CIGS, and amorphous silicon (α-Si). Absorber layer 106 can comprise material of a chalcopyrite family (e.g., CIGS) or kesterite family (e.g., BZnSnS and CZTS). In some embodiments, absorber layer 106 is a semiconductor comprising copper, indium, gallium and selenium, such as CuInₓGa₍₁₋ₓ₎Se₂, where x is in the range from 0 to 1. In some embodiments, absorber layer 106 is a p-type semiconductor comprising copper, indium, gallium and selenium. Absorber layer 106 has a thickness on the order of nanometers or micrometers, for example, 0.5 microns to 10 microns. In some embodiments, the thickness of absorber layer 106 is in the range of 500 nm to 2 microns.

Absorber layer 106 can be formed according to methods such as sputtering, chemical vapor deposition, printing, electrodeposition or the like. For example, CIGS is formed by first sputtering a metal film comprising copper, indium and gallium at a specific ratio, followed by a selenization process of introducing selenium or selenium containing chemicals in gas state into the metal firm. In some embodiments, the selenium is deposited by evaporation physical vapor deposition (PVD).

In some embodiments, the absorber material in absorber layer 106 is selected from copper indium gallium selenide (CIGS) or cadmium telluride (CdTe). The absorber material is a p-type semiconductor. In some embodiments, the absorber material in absorber layer 106 can also be CuInSe₂, CuInS₂, or CuGaSe₂.

At step 206, a buffer layer 108 is formed over absorber layer 106. Buffer layer 108 comprises a buffer material that is an n-type semiconductor in some embodiments. Examples of buffer layer 108 include but are not limited to CdS, ZnS ZnO, ZnSe, ZnIn₂Se₄, CuGaS₂, In₂S₃, MgO and Zn_{0.8}Mg_{0.2}O, in accordance with some embodiments. The thickness of buffer layer 108 is on the order of nanometers, for example, in the range of from 5 nm to 100 nm in some embodiments.

Formation of buffer layer 108 is achieved through a suitable process such as sputtering or chemical vapor deposition (CVD). For example, in some embodiments, buffer layer 108 is a layer of CdS, ZnS or a mixture of CdS and ZnO, deposited through a hydrothermal reaction or chemical bath deposition (CBD) in a solution. For example, in some embodiments, a buffer layer 108 comprising a thin film of ZnS is formed above absorber layer 106 comprising CIGS. Buffer layer 108 can be formed in an aqueous solution comprising ZnSO₄, ammonia and thiourea at 80° C. A suitable solution comprises 0.16M of ZnSO₄, 7.5M of ammonia, and 0.6 M of thiourea in some embodiments.

At step 208, a front transparent layer 110 is formed over buffer layer 108. As a part of a “window layer,” front transparent layer 110 can comprise two sublayers including a layer 112 comprising intrinsic ZnO (i-ZnO) and a front contact layer 114 (also referred to as transparent conductive layer 114) comprising transparent conductive oxide (TCO) or any other transparent conductive coating in some embodiments. The transparent conductive layer 114 can have a thickness less than 10 μm in some embodiments.

In some embodiments, layer 112 in front transparent layer 110 is made of undoped i-ZnO, which is used to prevent short circuiting in the photovoltaic device 100. In thin film solar cells, film thickness of absorber layer 106 comprising an absorber material such as CdTe and/or CIGS ranges from several nanometers to tens of micrometers. Other layers such as buffer layer 108, back contact layer 104, and front contact layer 114 comprising a transparent conductive coating are even thinner in some embodiments. If front contact layer 114 and back contact layer 104 are unintentionally connected because of defects in the thin films, an unwanted short circuit (shunt path) will be provided. Such phenomenon decreases performance of the photovoltaic devices, and can cause the devices to fail to operate within specifications. The decrease in efficiency due to the power dissipation resulting from the shunt paths can be up to 100%. In some embodiments, layer 112 comprising intrinsic zinc oxide (i-ZnO) without any dopants is thus provided between the front contact layer 114 and the back contact layer 104 to prevent short circuiting. For example, layer 112 can be disposed between buffer layer 108 and transparent conductive layer 114 as shown in FIGS. 1A-1B. Intrinsic ZnO having high electrical resistance can mitigate the shunt current and reduce formation of the shunt paths.

Front contact layer 114, which is a transparent conductive layer, is used in photovoltaic device 100 with dual functions: transmitting light to absorber layer 106 while also serving as a front contact to transport photo-generated electrical charges away to form output current. Transparent conductive oxides (TCOs) are used as front contacts in some embodiments. In some other embodiments, front contact layer 112 is made of a transparent conductive coating comprising nanoparticles such as metal nanoparticles or nanotube such as carbon nanotubes (CNT). Both high electrical conductivity and high optical transmittance of the transparent conductive layer are desirable to improve photovoltaic efficiency.

Examples of a suitable material for the front contact layer or transparent conductive layer 114 include but are not limited to transparent conductive oxides such as indium tin oxide (ITO), fluorine-doped tin oxide (FTO), aluminum-doped zinc oxide (AZO), gallium doped ZnO (GZO), alumina and gallium co-doped ZnO (AGZO), boron doped ZnO (BZO), or any combination thereof. A suitable material for the front contact layer 114 can also be a composite material comprising at least one of the transparent conductive oxide (TCO) or another conductive material, which does not significantly decrease electrical conductivity or optical transparency of front contact layer 114. The thickness of front contact layer 114 is in the order of nanometers or microns, for example in the range of from 0.3 nm to 2.5 μm in some embodiments.

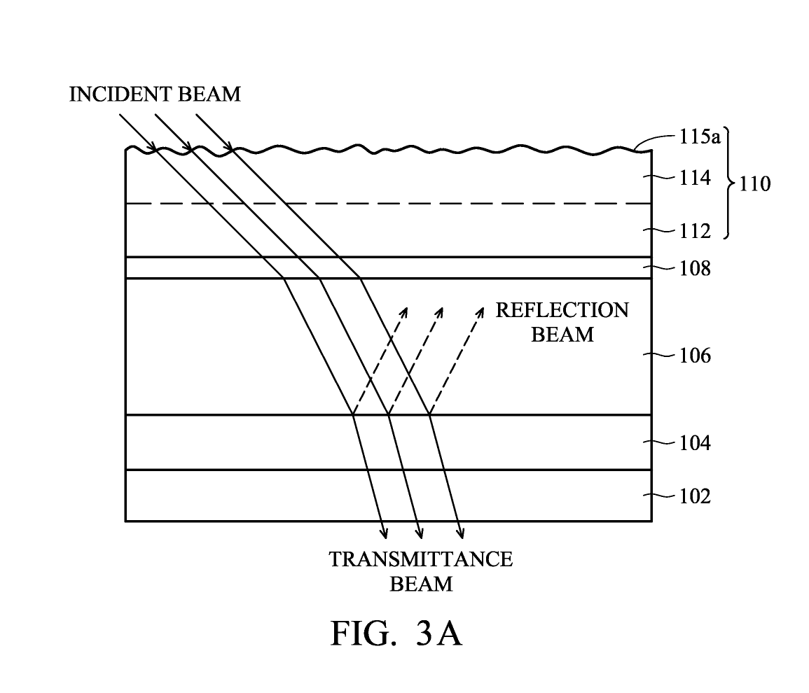

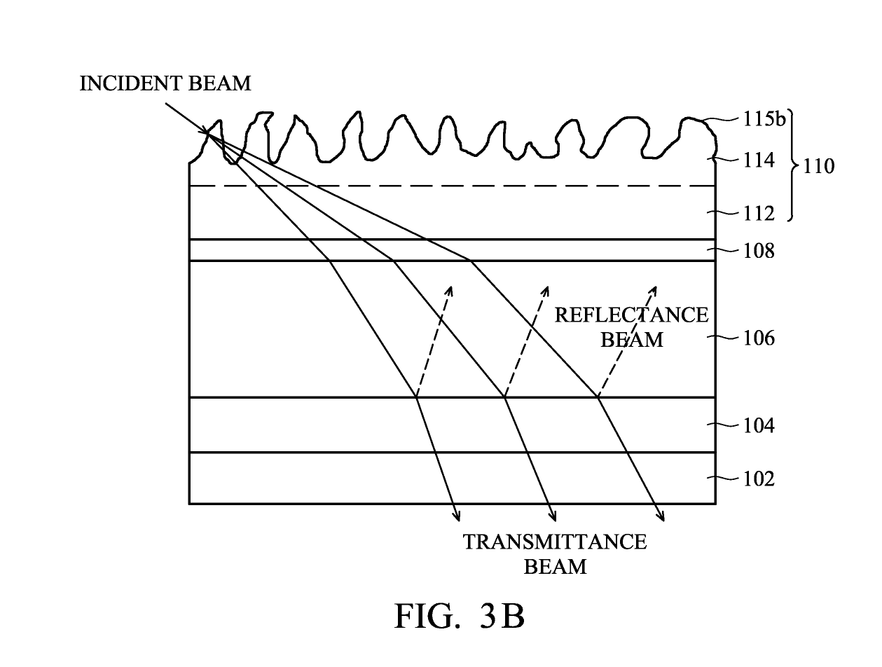

After formation of front transparent layer 110, the photovoltaic device can have a cross-section as shown in FIG. 1A. Examples of incident, reflection, and transmittance beams for the cross-section of FIG. 1A are shown in FIG. 3A. One way to improve internal quantum efficiency is to increase the thickness of absorber layer 106 to yield increased light absorption, but that results in decreased transmittance. Another way to improve internal quantum efficiency is to decrease the thickness of front transparent layer 110 (e.g., by decreasing the thickness of transparent conductive layer 114), but that results in increased sheet resistance (series resistance).

Another approach for increasing solar cell efficiency, in accordance with some embodiments of the present disclosure, is based on the observation that light transmittance is influenced by the structure of surface 115a of transparent conductive layer 114. Specifically, the surface structure of transparent conductive layer 114 affects light scattering, and treating the surface 115a with an acid increases the roughness of the surface (step 210 of FIG. 2), as shown in FIG. 1B. A solar cell formed by process 200 exhibits increased efficiency as explained below. Surface 115b shown in FIG. 1B is the result of treating surface 115a with acid. The increased surface roughness resulting from contact with acid induces more light scattering and improves light pathways, as shown in FIG. 3B. FIG. 3B shows that light incident upon surface 115b is scattered over a larger region, with a longer light pathway in absorber layer 106, than light incident upon surface 115a. The increased light scattering and longer light pathways result in an increase in external quantum efficiency.

An anti-reflection layer, e.g., comprising SiO₂ or MgF₂, can be formed above front transparent layer 110 in some embodiments.

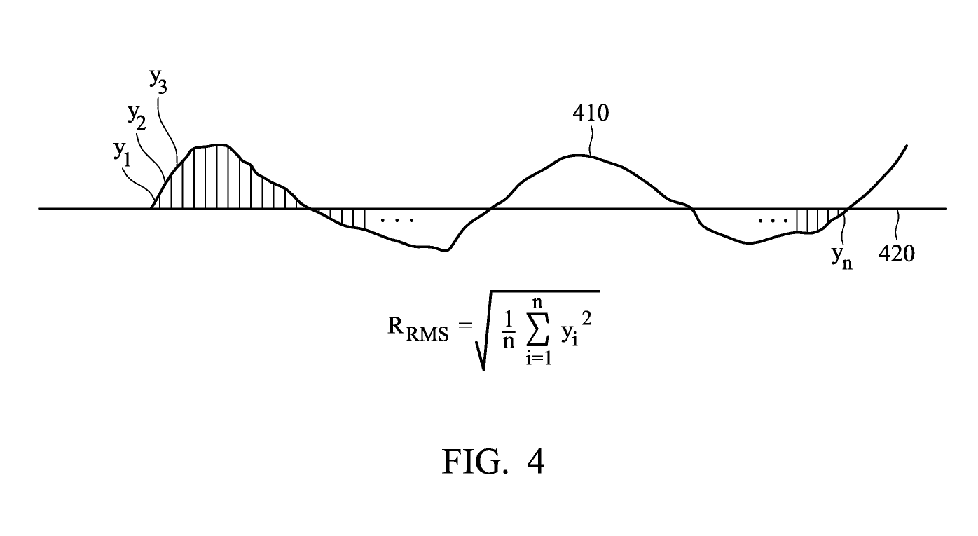

Surface roughness can be measured in various ways, including with a root mean square (RMS) measure. Referring to FIG. 4 as an example, the RMS roughness can be determined from a profile of the surface 410, by considering vertical deviations (vertical distances) y of the surface profile from a mean line 420 as follows:

R_{RMS}[(y₁²+y₂²+ . . . yₙ²)/n]^{1/2}

In the foregoing formula, n is the number of equally spaced points contained in the profile.

After step 208, but before step 210 (see FIG. 2), the RMS roughness of surface 115a is typically about 150 nm. After step 210, the RMS roughness of surface 115b is between about 300 nm and about 600 nm in some embodiments, e.g., about 500 nm. In some embodiments, the acid treatment increases the RMS roughness of the TCO surface by a factor of two to four times.

In some embodiments, surface 115a of transparent conductive layer 114 is treated by immersing at least a portion of the photovoltaic device (e.g., including at least the surface of the transparent conductive layer) in a liquid acid solution after TCO deposition. The concentration and immersion time are parameters that affect the resulting surface roughness and optical characteristics of the photovoltaic device 100. For immersion in acid, various acids such as HNO₃ or HCl can be used in the liquid acid solution. Immersing at least a portion of the photovoltaic device in a liquid acid solution having a concentration between about 0.1% and about 5% acid in water for HNO₃ or HCl liquid solutions, for a duration between about 1 and about 60 seconds, yields good results (e.g., yields RMS roughness between about 300 nm and about 600 nm, and increased light scattering and efficiency gain). If inappropriate acid concentration and/or immersion duration are used, the transparent conductive layer 114 can be damaged by the acid reducing the thickness of the transparent conductive layer 114 and inducing a porous structure in underlying (deeper) layers, both of which results can adversely impact conductivity of transparent conductive layer 114. An apparatus capable of fixing the position of the photovoltaic device, immersing at least the TCO surface in liquid acid, and withdrawing the TCO surface from the acid after the appropriate time duration can be used. Treating the surface of the transparent conductive layer 114 by immersing it in liquid acid that is at a temperature between about 20° C. and about 40° C. yields favorable roughness and dispersion properties.

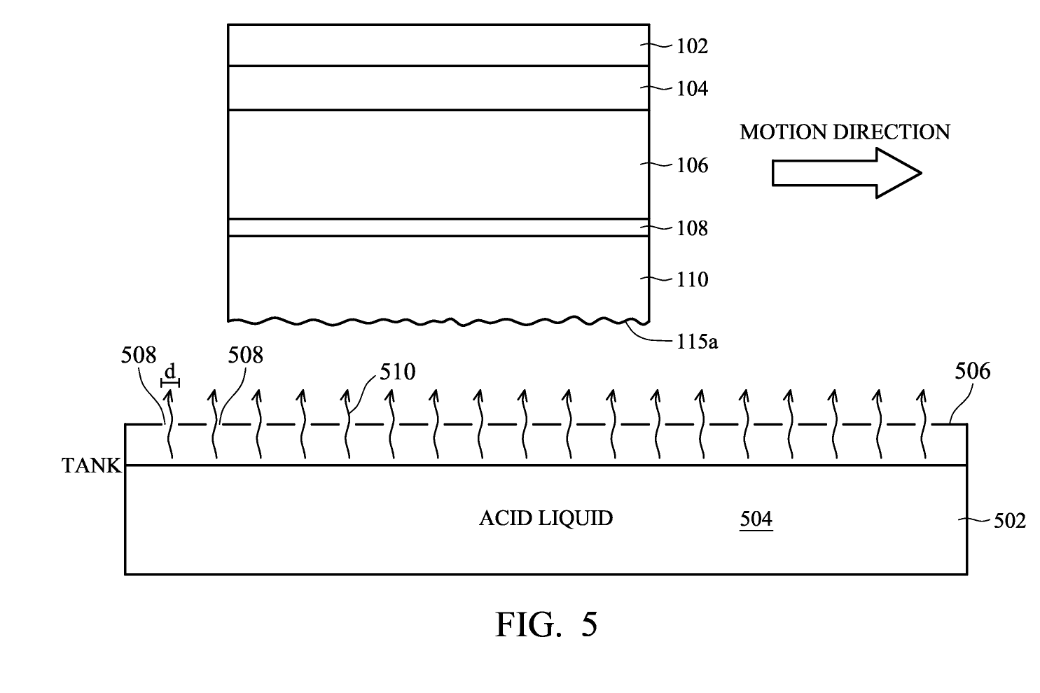

In other embodiments, an acid vapor can be used for treating the surface of transparent conductive layer 114. A benefit of the acid vapor approach is that because immersion in an acid is not needed, the process can be simpler, resulting in decreased component complexity and decreased cost. Referring to FIG. 5, a container (e.g., tank 502) contains a liquid acid solution, e.g., HNO₃ or HCl. Increasing the concentration of the liquid acid solution increases the amount of vapor that will rise from the surface of the liquid acid solution. Tank 502 has a cover 506 that covers the top of the tank. Cover 506 defines a plurality of apertures 508 through which vapor can rise from the surface of the liquid acid solution. After TCO deposition in the fabrication process for a photovoltaic device, the photovoltaic device is passed over the cover 506 of tank 502, e.g., as shown in FIG. 5 by the arrow labeled “Motion Direction.” An apparatus capable of controlling the movement of the photovoltaic device, e.g., using a motor and a controller, can be used. Movement is shown from left to right in FIG. 5, but any linear or nonlinear motion can be used. The rate at which the photovoltaic device is passed over the cover 506, the path along which the device is controlled to move, and/or the dimensions of apertures 508 affect the time during which the TCO surface is exposed to acid vapor and consequently affect the amount of acid vapor that is used to treat a given position on the TCO surface. In some embodiments, the apertures 508 range in size between about 1 mm and about 10 cm. The apertures can be circular, in which case the foregoing size correspond to a diameter, or they can be rectangular, in which case the size can correspond to a length or width, or they can be any other shape.

In other embodiments (not shown), an acid vapor can be applied by dispensing the vapor through at least one nozzle, while one of the nozzle or the substrate moves relative to the other one of the nozzle or substrate, until the entire surface of the TCO layer is treated with the vapor.

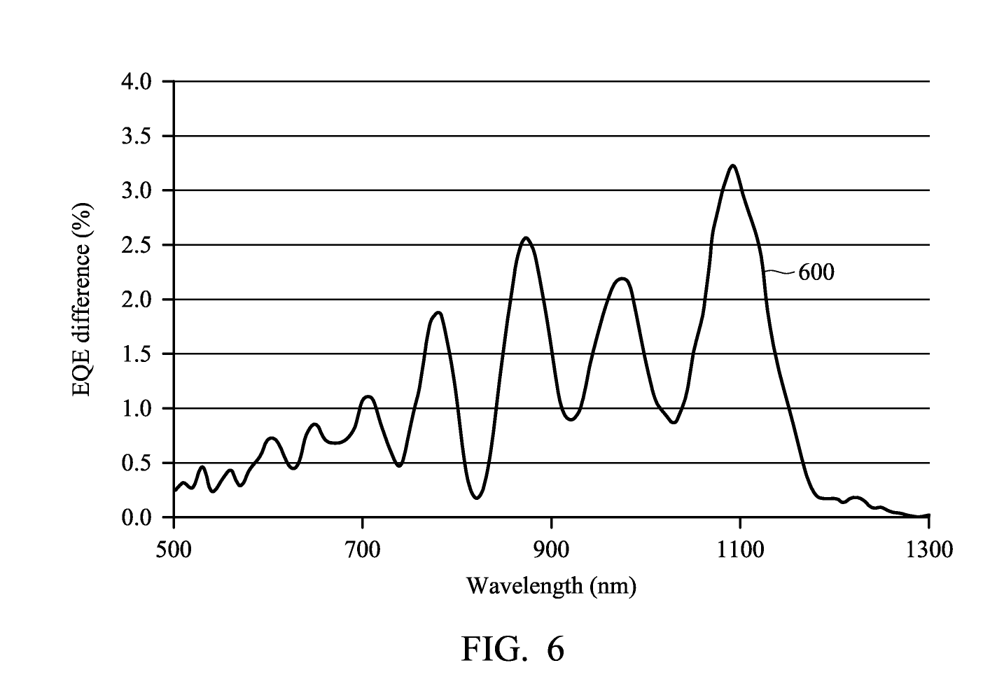

Treating the TCO surface with acid, whether by immersion in a liquid acid solution or by exposure to an acid vapor, increases quantum efficiency (e.g., external quantum efficiency) of the photovoltaic device 100. The quantum efficiency increases due to the longer light path in the absorber layer 106 induced by increased light scattering, which is in turn due to increased surface roughness. FIG. 6 is a plot of experimental results showing improved external quantum efficiency due to immersing the TCO surface 115a in a 2% concentration HNO₃ acid for 10 sec after TCO deposition. Plot 600 is the result of computing EQE₁−EQE₀, where EQE₀ is the external quantum efficiency of the solar cell before acid immersion and EQE₁ is the external quantum efficiency of the solar cell after acid immersion. The improvement in external quantum efficiency also advantageously contributes to increased short circuit current density (J_{sc}).

Thus, the quantum efficiency of a solar cell (photovoltaic device) is improved by treating the surface of a transparent conductive layer of the solar cell with an acid in various embodiments. Treatment of the surface of the transparent conductive layer with acid, e.g., by immersion in a liquid acid or by exposure to an acid vapor, is easy to integrate with existing solar cell production lines and results in high throughput at low cost.

In some embodiments, a method of fabricating a solar cell (e.g., process 200 in FIG. 2) includes forming a back contact layer above a substrate (step 202). The back contact layer can be formed by sputtering, chemical vapor deposition (CVD), printing, electrodeposition or the like. The material for the back contact layer can be selected based on the type of thin film photovoltaic device. The back contact layer can be etched to form a pattern.

An absorber layer for photon absorption is formed above the back contact layer (step 204) The absorber layer can be formed by sputtering, CVD, printing, electrodeposition or the like.

A buffer layer is formed above the absorber layer (step 206). The buffer layer is formed through a suitable process such as sputtering or CVD. For example, in some embodiments, the buffer layer is deposited through a hydrothermal reaction or chemical bath deposition (CBD) in a solution.

A transparent conductive layer is formed above the buffer layer (step 208). A layer comprising intrinsic ZnO (i-ZnO) can be formed above the buffer layer, and the transparent conductive layer can be formed above the i-ZnO layer. The i-ZnO layer can be formed by a process such as sputtering or metal organic chemical vapor deposition (MOCVD). MOCVD is a chemical vapor deposition process in which organic metallic compounds are evaporated into a processing chamber to react with each other and then are deposited as a film.

A surface of the transparent conductive layer is treated with an acid to increase roughness of the surface (step 210). The acid treatment can be achieved by immersing the surface of the transparent conductive layer in liquid acid or by exposing the surface to acid vapor, for example. In some embodiments, a solar cell formed by process 200 has benefits including increased quantum efficiency.

In some embodiments, a method of processing a transparent conductive layer of a solar cell includes forming the transparent conductive layer above a buffer layer. The transparent conductive layer can be formed by sputtering, CVD, printing, electrodeposition or the like. A surface of the transparent conductive layer is etched with an acid, e.g., by immersing the surface in liquid acid or by exposing the surface to acid vapor. In some embodiments, the transparent conductive layer that results from this process exhibits increased light scattering and results in quantum efficiency gain.

In some embodiments, a photovoltaic device (solar cell) has a substrate (e.g., substrate 102), a back contact layer (e.g., back contact layer 104) disposed above the substrate, an absorber layer (e.g., absorber layer 106) disposed above the back contact layer, a buffer layer (e.g., buffer layer 108) disposed above the absorber layer; and a transparent conductive layer (e.g., transparent conductive layer 114) disposed above the buffer layer. A surface (e.g., surface 115b) of the transparent conductive layer has a root mean square roughness in a range from about 300 nm to about 600 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of fabricating a photovoltaic cell, the method comprising:
forming a back contact layer above a substrate;
forming an absorber layer above the back contact layer;
forming a buffer layer above the absorber layer;
forming a transparent conductive layer above the buffer layer; and
treating a surface of the transparent conductive layer with an acid to increase roughness of the surface.

2. The method of claim 1, wherein treating the surface of the transparent conductive layer includes immersing at least the surface of the transparent conductive layer in a liquid acid solution.

3. The method of claim 2, wherein the surface is immersed in the liquid acid solution for a duration between about 1 second and about 60 seconds.

4. The method of claim 2, wherein the surface of the transparent conductive layer is treated at a temperature between about 20° C. and about 40° C.

5. The method of claim 2, wherein the liquid acid solution comprises HNO₃.

6. The method of claim 2, wherein the liquid acid solution comprises HCl.

7. The method of claim 2, wherein the liquid acid solution has a concentration between about 0.1% and about 5% acid in water.

8. The method of claim 1, wherein treating the surface of the transparent conductive layer includes exposing the surface to an acid vapor.

9. The method of claim 8, wherein exposing the surface to the acid vapor includes passing the surface over a cover of a tank containing a liquid acid solution, the cover defining a plurality of apertures allowing passage of the vapor therethrough.

10. The method of claim 9, wherein each aperture has a dimension between about 1 mm and about 10 cm.

11. A method of processing a transparent conductive layer of a photovoltaic cell, the method comprising:
forming the transparent conductive layer above a buffer layer; and
etching a surface of the transparent conductive layer with an acid.

12. The method of claim 11, wherein etching the surface of the transparent conductive layer includes immersing at least the surface of the transparent conductive layer in a liquid acid solution.

13. The method of claim 12, wherein the surface is immersed in the liquid acid solution for a duration between about 1 and about 60 seconds.

14. The method of claim 12, wherein the surface of the transparent conductive layer is etched at a temperature between about 20° C. and about 40° C.

15. The method of claim 12, wherein the liquid acid solution comprises HNO₃.

16. The method of claim 12, wherein the liquid acid solution comprises HCl.

17. The method of claim 12, wherein the liquid acid solution has a concentration between about 0.1% and about 5% acid in water.

18. The method of claim 11, wherein etching the surface of the transparent conductive layer includes exposing the surface to an acid vapor.

19. The method of claim 18, wherein exposing the surface to the acid vapor includes passing the surface over a cover of a tank containing a liquid acid solution, the cover defining a plurality of apertures allowing passage of the vapor therethrough.

20. A photovoltaic device comprising:
a substrate;
a back contact layer disposed above the substrate;
an absorber layer disposed above the back contact layer;
a buffer layer disposed above the absorber layer; and
a transparent conductive layer disposed above the buffer layer, a surface of the transparent conductive layer having a root mean square roughness in a range from about 300 nm to about 600 nm.

21. An acid liquid treatment method, the method comprising the steps of:
forming a transparent conductive oxide layer having a thickness of 10 microns or less;
treating the transparent conductive oxide layer surface with an acid containing liquid HNO3 in a concentration range from 0.1% to 5%, in a temperature range from 20° C. to 40° C., for a time in a range from 21 seconds to 60 seconds.
